(19) United States
(12) Patent Application Publication
(10) Pub. No.: US 2007/0126030 A1
(43) Pub. Date: Jun. 7, 2007

(54) Semiconductor device and method for manufacturing same, and semiconductor wafer

(75) Inventor: Mutsuyoshi Ito, Kanagawa (JP)

Correspondence Address: ROBERT J. DEPKE;LEWIS T. STEADMAN, ROCKEY, DEPKE, LYONS AND KITZINGER, LLC, SUITE 5450 SEARS TOWER, CHICAGO, IL, 60606-6306, US

(73) Assignee: SONY CORPORATION

(21) Appl. No.: 11/601,971

(22) Filed: Nov. 18, 2006

(30) Foreign Application Priority Data
Dec. 2, 2005 (JP) P2005-348854

(51) Int. Cl. H01L 27/10

(52) U.S. Cl. 257/211

(57) ABSTRACT

Disclosed herein is a semiconductor device including: a semiconductor chip; a first insulating layer covering the semiconductor chip in a condition where at least a portion of a terminal electrode of the semiconductor chip is exposed; a second insulating layer formed over the first insulating layer; and a rewiring layer extracting the terminal electrode of the semiconductor chip via the second insulating layer to a position of connection with an external circuit; wherein an underlying layer for plating connected with the terminal electrode is provided in an existing area of the terminal electrode alone or in a region covering from the existing area to above the first insulating layer, and at least a part of the rewiring layer is formed of a plated layer formed on the underlying layer.

### CROSS REFERENCES TO RELATED APPLICATIONS

The present invention contains subject matter related to Japanese Patent Application JP 2005-348854 filed in the Japanese Patent Office on Dec. 2, 2005, the entire contents of which being incorporated herein by reference.

### BACKGROUND OF THE INVENTION

1. Field of the Invention

This invention relates to a semiconductor device and a method for manufacturing same, and also to a semiconductor wafer on which semiconductor chips are sequentially disposed. More particularly, it relates to a semiconductor device suited for wafer-level chip scale package and a method for manufacturing same.

2. Description of the Related Art

Hitherto, packages for semiconductor chip have been mainly ones wherein individual diced semiconductor chips are mounted on a lead frame, electrically connected at terminal electrodes thereof to the lead frame such as by a wire bonding method, and sealed with an insulating resin. In recent years, however, portable small-sized electronic devices including portable cell phones have been made small in size and light in weight for the sake of portability. Accordingly, there is a demand for small-sized, lightweight and thin semiconductor devices used for these devices. To very effectively meet this demand, a semiconductor package called wafer-level chip scale package has been frequently adopted by many makers for semiconductor device in recent years.

With a chip scale package, a rewiring layer for extracting terminal electrodes of a semiconductor chip at positions of connection with an external circuit and electrodes for external connection with the external circuit at the extracted positions are formed at a region of substantially the same size as the semiconductor chip and are sealed such as with an insulating resin. This enables high-density mounting on a mounting substrate.

Among chip scale packages, the wafer-level chip scale package (wafer-level CSP) is made by forming an insulating resin layer on an active face of a semiconductor wafer on which a plurality of semiconductor chips are disposed in position, forming a rewiring layer and electrodes for external connection via the insulating resin layer, and dicing the semiconductor wafer into individual chip scale packages. This manufacturing method enables a number of semiconductor chips formed on the semiconductor wafer to be processed collectively, and can be thus a chip scale package manufacturing method that is drastically rationalized, so that attention has now been paid to this as a method of improving mass productivity of chip scale packages and providing chip scale packages at low costs.

FIG. 5 is a plan view showing a semiconductor wafer on which a plurality of semiconductor chips are sequentially disposed, and FIGS. 6A to 6G are, respectively, a schematic sectional view showing a manufacturing step of wafer-level CSP depicted in JP-A-2001-521288 (pages 15 to 20, FIG. 2) (hereinafter referred as Patent Document 1). It will be noted that FIGS. 6A to 6G are each a section at a position indicated by line 9A-9A of FIG. 5. Referring to FIGS. 5 to 6G, the manufacturing steps of, typical wafer-level CSP in related art are illustrated.

Initially, as shown in FIG. 6A, a substrate 1 to be processed into wafer-level CSP is provided. A plurality of semiconductor chips 30 are sequentially disposed on the substrate 1, with its surface being covered with a protective film (wafer passivation layer) 3 except for terminal electrodes 2. As shown in the plan view of FIG. 5, the substrate 1 is a silicon wafer that has, for example, an orientation flat or notch with a diameter of 8 inches and a thickness of 725 μm, and a number of semiconductor chips 30 are sequentially disposed in the vicinity of the surface. When the substrate 1 is diced along scribing lines 40, individual semiconductor chips 30 are separated into pieces.

Next, as shown in FIG. 6B, a first passivation layer 101 is formed. The material for the first passivation layer 101 includes a benzocyclobutene (BCB) resin or a polyimide resin. An insulating resin layer is formed by a coating method such as spin coating and patterned by photolithography and etching to form an opening 107 through which the terminal electrode 2 is exposed.

As shown in FIG. 6C, a metal layer 102 made of a stacked structure of alumina/nickel-vanadium/copper (Al/NiV/Cu) or titanium/nickel-vanadium/copper (Ti/NiV/Cu) is formed over the entire surface of the substrate 1 by sputtering.

Thereafter, as shown in FIG. 6D, the metal layer 102 is patterned by photolithography and etching to form a rewiring layer 103 and a bump pad 104.

Next, as shown in FIG. 6E, a second passivation layer 105 is formed. The material for the second passivation layer 105 includes benzocyclobutene (BCB) resin or a polyimide resin, and an insulating resin layer is formed by a coating method such as spin coating, followed by patterning by photolithography and etching to form an opening through which the solder bump pad 104 is exposed. The second passivation film 105 also serves as a solder resist.

As shown in FIG. 6F, a solder ball 106 connecting with the solder bump pad 104 is formed.

As shown in FIG. 6G, the substrate 1 is diced along the scribing lines into pieces to finally provide each wafer-level CSP 100.

Although, in the above example, the metal layer 102 has been formed by sputtering, an example of forming such a metal layer by combination with an electrolytic plating method is shown in Japanese Patent Laid-open No. 2004-214501 (pages 7 to 9, FIGS. 2 to 4) (hereinafter referred to as Patent Document 3).

FIGS. 7A to 7G are, respectively, a sectional view showing an instance of a manufacturing step of wafer-level CSP 110 in case where an electrolytic plating method is used in combination. It is to be noted that the steps shown in FIGS. 6A and 6B are same as in the above case and are omitted herein. Referring to FIGS. 7A to 7G, the manufacturing procedure of wafer-level CSP 110 is illustrated. It will be noted that members whose shapes slightly differ from each other and which have substantially the same function in view of the concept of the invention are designated by the same reference numerals herein and whenever they appear hereinafter.

In the same manner as in FIGS. 6A and 6B, the substrate 1 is formed thereon with the first passivation layer 101 and the opening 107 for exposure of the terminal electrode 2. Next, as shown in FIG. 7A, a seed metal layer 111 made of a single layer of nickel (Ni) or chromium (Cr) or a multilayer of titanium/copper (Ti/Cu) is formed entirely on the substrate by sputtering.

Next, as shown in FIG. 7B, a resist mask 112 for plating having a pattern corresponding to the pattern of a rewiring layer 114 and a solder bump pad 115 to be subsequently made is formed through patterning by photolithography.

As shown in FIG. 7C, an electrolytic copper-plated layer 113 is formed by an electrolytic plating method using the seed metal layer 111 as a seed layer and the plating resist mask 12 as a mask.

Thereafter, as shown in FIG. 7D, after removal of the plating resist mask 112 by dissolution, the seed metal layer 111 formed therebeneath is removed by etching to complete the rewiring layer 114 and the solder bump pad 115.

Subsequently, as shown in FIGS. 7E to 7G, a second passivation layer 105 and a solder ball 106 are formed, followed by dicing into individual pieces of wafer-level CSP 110 in the same manner as in FIGS. 6E to 6G to complete the manufacture of the wafer-level CSP 110.

In the manufacturing methods of such wafer-level CSP 100 and CSP 110 as set forth hereinabove, a relatively expensive manufacturing apparatus used in a wafer process of manufacturing a semiconductor is used. For instance, the metal layer 102 and the seed metal layer 111 are, respectively, formed by use of a sputtering apparatus, and the first passivation layer 101 and the second passivation layer 105 are, respectively, formed by a spin coater. The materials for the first and second passivation layers 101 and 105 include liquid resins made of BCB, polyimides and the like, which are relatively expensive ones used as a material for manufacturing semiconductors. Eventually, the wafer-level CSP 100 and CSP 110 become high in cost, thus not satisfactorily showing the feature of wafer-level CSP that low costs can be realized.

With high-frequency integrated circuit (IC) chips, as the first passivation layer 101 is thicker, the high-frequency characteristic is more improved, so that it is preferred to form the first passivation layer 101 in a thickness of about 40 μm. In this connection, however, if the first passivation layer 101 is formed of a liquid resins such as BCB, a polyimide or the like, a difficulty is involved in forming a resin layer having a thickness not smaller than about 10 μm. Accordingly, the chip for high frequency raises a problem in that high-frequency characteristics lower owing to the shortage in thickness of the first passivation layer 101.

With the case where an insulating resin layer and a rewiring layer are alternately stacked plurally to form a multi-layered rewiring layer, when the insulating resin layer is formed of a liquid resin, irregularities caused by the rewiring layer is liable to lead to an impediment along with a problem in that an increasing number of layers result in the drastic degradation of manufacturing yield.

On the other hand, according to Japanese Patent Laid-open No. 2004-101850 (page 5, FIG. 1) (hereinafter referred to as Patent Document 2), there have been proposed a photosensitive organic and inorganic composite material made of a photosensitive resin and an inorganic filler, and a semiconductor device using this photosensitive organic and inorganic composite material. In this Patent Document, there is shown a method of forming an insulating resin layer used for forming a rewiring layer by lamination of an insulating resin sheet.

According to this method, a photosensitive resin solution mixing an inorganic filler therein is coated onto a thin copper foil, after which the solvent is evaporated to allow a photosensitive resin layer to be semi-solidified, thereby providing a photosensitive resin layer-coated copper foil (RCC: resin-coated copper). Next, the RCC and a dry-film plating film resist are laminated, by use of a roll laminator, to the surface of a semiconductor wafer wherein semiconductor chips have been incorporated. Thereafter, the dry-film plating film is patterned by photolithography to form a plating resist mask shaped correspondingly to a rewiring layer and the like, followed by forming, on the copper foil at mask-free openings, an electrolytic plated layer wherein a copper layer/nickel layer/gold layer are stacked.

Next, the plating resist mask is removed, after which the copper foil is etched using the gold layer as a mask so that the copper foil is patterned in the same pattern as the electrolytic plated layer thereby completing a rewiring layer and a solder bump pad. Subsequently, the photosensitive resin layer in the region where the copper foil of RCC has been removed is patterned by photolithography to form an opening to expose a terminal electrode of the semiconductor wafer. Thereafter, the remaining photosensitive resin layer is completely cured to complete the insulating resin layer. The terminal electrode and the rewiring layer are electrically connected by wire bonding.

In Patent Document 2, it is stated that the effect of this invention is such that since the photosensitive organic and inorganic composite material contains an inorganic filler, its thermal expansion coefficient differs from that of a substrate slightly, so that there arises no problem on the occurrence of cracks in the insulating resin layer caused by a change in temperature and thus, a semiconductor device of excellent reliability can be provided.

Further, because the insulating resin layer and rewiring layer are formed using the semi-solidified photosensitive resin layer-coated copper foil (RCC), no problem arises as resulting from the use of a liquid resins such as BCB or a polyimide set out with regard to Patent Document 1.

In Patent Document 2, however, only an instance of a wire bonding method is shown for a method of electric connection between the terminal electrode of a semiconductor chip and the rewiring layer. The wire bonding method is one wherein connections are made one by one, for which limitation is placed on productivity. Hence, this method is unsuited for a method of manufacturing wafer-level CSP which intends for collective processing of a wafer as a whole. In addition, this method has the problems in that the wire portion becomes bulky, thus leading to a great thickness of the resulting package and that upon patterning, the terminal electrode made of aluminium is altered in nature in the course of removing a resin that has not been cleared off by development, thereby increasing a fraction defective of a wire-bonded portion.

In Patent Document 3, there has been proposed an example of conveniently using a copper foil-laminated adhesive sheet as a high-frequency shield layer for the fabrication of wafer-level CSP that is usable in the field of high-frequency communication and is of the fan-in type. In this case, an insulating resin layer used for the formation of a rewiring layer is separately formed of a photosensitive liquid resin.

FIG. 8 is a sectional view showing a structure of wafer-level CSP 120 illustrated in Patent Document 3. As shown in FIG. 8, with wafer-level CSP 120, a semiconductor chip 30 is incorporated in a substrate 1 such as a silicon wafer, in which terminal electrodes 2 are formed as exposed from a protective film (passivation film) 3.

For the fabrication of the wafer-level CSP 120, a copper foil-attached adhesive sheet is thermally pressed on an active surface side of the substrate 1 to form a copper foil-laminated adhesive layer 121. The copper foil-laminated adhesive sheet made of a thin adhesive layer 122 and a copper foil 123 and has been beforehand formed with an opening having a diameter of about 100 μm at a position corresponding to the terminal electrode 2. Next, a photosensitive resin layer 124 made of a polyimide is formed over the entire surface of the copper foil-laminated adhesive layer 121 including the openings, after which a connection hole arriving at the terminal electrode 2 and the adhesive layer 122 is formed in the photosensitive resin layer 124 by photolithography. For the material of the photosensitive resin layer 124, polyimides resins, epoxy resins, polybenzooxazole (PBO) resins, BCB resins and the like are used.

Thereafter, in the same manner as having been illustrated with reference to FIGS. 7A to 7G, a rewiring layer 126 and the like are formed. More particularly, a seed metal layer (not shown) made of nickel (Ni) or chromium (Cr) is formed on the surface of the photosensitive resin layer 124 and the inner wall surfaces of the connection hole by sputtering, followed by patterning by photolithography to form a resist mask (not shown) having a pattern corresponding to the shapes of a rewiring layer 126, and bump pads 127, 129 to be made. An electrolytic copper-plated layer, which serves to constitute extraction lines 125, 128, rewiring layer 126, and bump pads 127, 129, is formed on the seed metal layer at portions thereof not covered with the resist mask by an electrolytic plating method. Next, after removal of the resist mask by dissolution, the seed metal layer disposed therebeneath is removed by etching to complete the extraction lines 125 and 128, rewiring layer 126 and solder bump pads 127 and 129.

Subsequently, after formation of an insulating resin layer over the entire surface, photolithography is performed for patterning to expose the solder bump pads 127 and 129 alone, then form a cover coat 130 serving also as a solder resist. Next, solder balls 131 are formed in contact with the solder bump pads 127 and 129, respectively, to complete the fabrication of wafer-level CSP 120.

In Patent Document 3, it is stated that the use of a copper foil-laminated adhesive sheet leads to the following effects. That is, because the copper foil 123 of the copper foil-laminated adhesive sheet is left between the semiconductor chip 30 and the rewiring layer 126 as a ground layer, the electromagnetic wave from the printed circuit board ascribed to a high-frequency current is interrupted by means of the copper foil 123, thereby preventing noises from occurring in the circuit of the semiconductor chip 30. In addition, the adhesive layer 122 of the copper foil-laminated adhesive sheet is pressed in a semi-cured condition, so that volumetric shrinkage becomes much smaller than with the case where a photosensitive resin solution is coated to form an insulating resin layer. Thus, a much smaller stress caused between the wafers results, with no problem based on the warpage of the wafers. Since the adhesive layer 122 is far lower in cost than a photosensitive resin layer, the resulting wafer-level CSP 120 can be made inexpensively.

In the above Patent Document, however, there has not been proposed and suggested the formation of a rewiring layer of wafer-level CSP 120 and an insulating resin layer for forming the rewiring layer by use of a copper foil-laminated adhesive sheet. More particularly, the photosensitive resin layer 124 used to form the rewiring layer is separately formed using a photosensitive liquid resin such as a polyimide. Accordingly, the resulting wafer-level CSP 120 becomes high in cost, like the wafer-level CSP 100 of the afore-indicated Patent Document 1, with the attendant problems that full use is not made of the feature of wafer-level CSP and that where the rewiring layer is formed as multilayered, an increasing number of layers result in a drastic reduction of yield.

Although it is stated that the copper foil-laminated adhesive sheet has been beforehand formed with openings with a diameter of about 100 μm by drilling positions corresponding to the terminal electrodes 2, there is a concern as to whether a multitude of fine openings can be formed precisely by drilling without impeding productivity and yield.

### SUMMARY OF THE INVENTION

As having stated hereinbefore, the method of manufacturing wafer-level CSP is considered to be a very excellent chip scale package manufacturing method because a number of semiconductor chips sequentially disposed on a semiconductor wafer can be processed collectively.

However, as stated above, the wafer-level CSP manufacturing methods in related art do not make full use of the features of cost-reducible wafer-level CSP owing to the facts that expensive manufacturing apparatus and materials used in semiconductor manufacturing processes are used and that manufacturing methods developed in other fields are employed as they are, e.g. a wire bonding method is used in combination.

Additionally, individual semiconductor chips are formed in the same manner as with semiconductor chips in related art which are packaged after separation into individual pieces, and there has been made no idea of subjecting semiconductor chips to pre-processing while assuming a packaging step. For instance, the packaging step is carried out while exposing the terminal electrode of a semiconductor chip to outside, under which the terminal electrode is liable to suffer degradation in the packaging step and measures to be taken in the packaging step is apt to be limited to techniques in related art.

Under these circumstances in the art, it is desirable to provide a semiconductor device that makes full use of the feature of a cost-reducible wafer-level chip scale package and a method for manufacturing same.

It is also desirable to provide a semiconductor wafer in which packaged semiconductor chips are sequentially disposed.

According to one embodiment of the present invention, by a semiconductor device which includes a semiconductor chip; and a first insulating layer covering the semiconductor chip in a condition where at least a portion of a terminal electrode of the semiconductor chip is exposed. The semiconductor device further includes a second insulating layer formed over the first insulating layer; and a rewiring layer extracting the terminal electrode of the semiconductor chip via the second insulating layer to a position of connection with an external circuit. The semiconductor device still further has an underlying layer for plating connected with the terminal electrode which is provided in an existing area of the terminal electrode alone or in a region covering from the existing area to above the first insulating layer. Further, at least a part of the rewiring layer is formed of a plated layer formed on the underlying layer.

According to another embodiment of the invention, there is provided a method for manufacturing such a semiconductor device as set out above, the method including the steps of: providing a semiconductor wafer having a plurality of semiconductor chips sequentially; forming a first insulating layer to cover individual semiconductor chips in such a state that at least a part of an terminal electrode of each semiconductor chip is exposed; and forming an underlying layer for plating, connected with the terminal electrode, in an existing region of the terminal electrode or in an area covering from the existing region to above the first insulating layer collectively against the plurality of semiconductor chips formed on the semiconductor wafer. The method for manufacturing the semiconductor device further including the steps of: forming a second insulating layer over the first insulating layer; forming an opening in the second insulating layer to expose the terminal electrode; forming a rewiring layer, at least a part of which is formed by a plating method, from the opening to above the second insulating film, thereby providing a plurality of semiconductor devices sequentially disposed on the semiconductor wafer; and separating the plurality of semiconductor devices into pieces, each containing at least one semiconductor device.

According to a further embodiment of the invention, such a semiconductor wafer sequentially disposing thereon a plurality of semiconductor devices of the type mentioned above is also provided.

According to the semiconductor device of the embodiments of the present invention, assuming that at least a part of the rewiring layer is formed of a plated layer, an underlying layer for plating that is connected to the terminal electrode is provided in an existing region of the terminal electrode or in a region covering from the existing region to above the first insulating layer. The provision of the underlying layer enables at least a part of the rewiring layer connected to the terminal electrode to be easily, reliably formed by plating. Eventually, the semiconductor device of the invention can be inexpensively manufactured since the rewiring layer can be formed by a simple device in high yield without resorting to an expensive sputtering apparatus.

The underlying layer for plating can be formed of a material that functions as a protective layer of the terminal electrode. In this case, the terminal electrode is protected with the underlying layer for plating, under which when an opening is formed so as to expose the terminal electrode, various methods such as radiation of a laser beam, etching and the like may be used. The terminal electrode is prevented from changing in nature and degradation in the course of the steps of forming the rewiring layer including the opening formation step, so that the semiconductor device of the invention can be manufactured in high manufacturing yield.

The method for manufacturing a semiconductor device according to the embodiments of the present invention is one which has steps necessary for fabricating the semiconductor device of the invention and is able to manufacture the device in high manufacturing yield.

Especially, there are carried out the steps of: providing a semiconductor wafer having a plurality of semiconductor chips sequentially; forming a first insulating layer to cover individual semiconductor chips in such a state that at least a part of an terminal electrode of each semiconductor chip is exposed; and forming an underlying layer for plating, connected with the terminal electrode, in an existing region of the terminal electrode or in an area covering from the existing region to above the first insulating layer collectively against the plurality of semiconductor chips formed on the semiconductor wafer. Further, there are carried out the steps of: forming a second insulating layer over the first insulating layer; forming an opening in the second insulating layer to expose the terminal electrode; and forming a rewiring layer, at least a part of which is formed by a plating method, from the opening to above the second insulating film, whereby a plurality of semiconductor chips can be manufactured collectively to realize high productivity, high stability of quality and low manufacturing costs.

The semiconductor wafer of the invention is an intermediate product obtained by subjecting a plurality of semiconductor chips disposed thereon to collective packaging, and separation into individual chip pieces enables a number of semiconductor devices to be obtained in good productivity.

The above and other features and advantages of the present invention will become apparent from the following description when taken in conjunction with the accompanying drawings which illustrate preferred embodiments of the present invention by way of example.

### BRIEF DESCRIPTION OF THE DRAWINGS

FIGS. 1A and 1B are, respectively, a plan view and a sectional view showing the structure of wafer-level CSP according to Embodiment 1 of the present invention;

FIGS. 2A to 2L are, respectively, sectional views showing the steps of manufacturing the wafer-level CSP according to Embodiment 1 of the present invention;

FIGS. 3A to 3C are, respectively, sectional views showing a part of a manufacturing procedure of wafer-level CSP according to a modification of Embodiment 1 of the present invention;

FIGS. 4A to 4G are, respectively, sectional views showing the manufacturing steps of waver-level CSP according to Embodiment 2 of the present invention;

FIG. 5 is a plan view showing a semiconductor wafer having a plurality of semiconductor chips disposed sequentially thereon;

FIGS. 6A to 6G are, respectively, the manufacturing steps of wafer-level CSP illustrated in Patent Document 1;

FIGS. 7A to 7G are, respectively, sectional views showing the manufacturing steps of wafer-level CSP wherein a rewiring layer is formed in combination with an electrolytic plating method; and

FIG. 8 is a sectional view showing the structure of wafer-level CSP illustrated in Patent Document 3.

### DETAILED DESCRIPTION OF THE PREFERRED EMBODIMENTS

In the semiconductor device and method for manufacturing same according to the invention, the underlying layer for plating is constituted of a single layer or a stacked multilayer, of which a contact portion with the terminal electrode is preferably formed by an electroless plating method. For instance, in case where a layer made of a metal whose ionization tendency is smaller than a metal for the terminal electrode is deposited as the contact potion by use of a difference in ionization tendency, the metal layer is self-alignedly formed relative to the terminal electrode. This does not need any patterning step thereby forming the contact portion simply and reliably.

For example, where the terminal electrode is made of aluminum, a metal forming the contact portion should preferably be one having a small ionization tendency, e.g. zinc. The contact portion made of zinc can be formed by zincating of aluminium constituting the terminal electrode.

It is also preferred that the underlying layer for plating is constituted of a single layer or a stacked multilayer, in which the uppermost portion thereof is made of a layer of a high melting metal. In doing so, when the opening is formed by irradiation, for example, of a laser beam, the high melting metal layer at the uppermost portion is resistant to high temperatures caused by the irradiation of the laser beam and serves to protect the lower layer of the underlying layer for plating and the terminal electrode. This high melting metal is not limited in type and should preferably be high in light reflectivity and exhibit good adhesion to a metal for plated layer.

For instance, where the metal for the plated layer is copper, it is preferred that the layer made of a high melting metal is one made of nickel, in which at least a part of the latter layer is formed of nickel by electroless plating. The nickel layer is excellent as an underlying layer for copper layer and can be formed by electroless plating using, as a seed layer, the zinc layer formed by the zincating treatment. This allows reliable self-aligned formation relative to the terminal electrode, like the zinc layer. Thus, no patterning step is needed, thereby enabling the manufacturing process to be simplified.

According to the zincating treatment and electroless plating of nickel, a nickel plated layer can be eventually formed firmly, strongly and self-alignedly on the terminal electrode.

At least a part of the plated layer should preferably be an electroless plated layer formed by an electroless plating method. The electroless plated layer may be formed without resorting to a large-scaled apparatus such as a vapor deposition apparatus.

Although the electroless plated layer may be used as a plated single layer, the electroless plated layer may be provided as a seed layer, on which an electrolytic plated layer formed by an electrolytic plating method is stacked to provide a plated layer in combination.

It is preferred that an insulating resin sheet is laminated to a surface of the first insulating layer to form the second insulating layer. In this way, the second insulating layer can be formed of an inexpensive material such as an epoxy resin without use of a relatively expensive manufacturing apparatus such as a spin coater or the like and also of relatively expensive liquid resin materials such as BCB, a polyimide and the like ordinarily used as a material of semiconductor.

The insulating layer having a high accuracy in thickness can be formed. When the thickness of a resin layer in the insulating resin layer is varied, the thickness of the second insulating layer can be readily changed. In addition, because the second insulating layer can be readily formed in a thickness of 10 μm or over, e.g. 40 μm, which is difficult to attain when using a liquid resin, so that the high-frequency characteristics of a semiconductor chip may not be impeded by means of the second insulating layer.

The insulating resin layer of the insulating resin sheet is pressed in a semi-solidified condition, and thus, volumetric shrinkage is much smaller than in the case where a solution of a resin is coated to form an insulating resin layer. As a result, the stress caused between wafers becomes much smaller, with no problem being involved based on the warpage of wafer

Where an insulating resin layer and a rewiring layer are alternately stacked plurally to form a multilayered rewiring layer, the irregularities caused by the rewiring layer is reliably flattened by means of the semi-solidified insulating resin layers. This permits multilayering more readily in higher manufacturing yield than in the case where a liquid resin is used for flattening.

Further, a copper foil-attached insulating resin sheet may be used as the insulating resin sheet. In this case, the copper foil layer is patterned, and part thereof may be used as a part of the rewiring layer. If the copper foil layer is too thick, the thickness is reduced by etching over the entire surface, followed by patterning for use as a part of the rewiring layer. The copper coil layer may be used as an aid permitting easy handling in the course of the formation of the second insulating layer and may be removed after the formation of the second insulating layer.

The opening may be formed by irradiation of a laser beam. According to the irradiation of a laser beam, the irradiation position is optically changed successively, whereupon a multitude of openings can be formed efficiently. The laser beam used is not critical with respect to the wavelength thereof, and where it is required to accurately form fine holes as an opening, it is preferred to use a UV laser beam of a short wavelength that is suited for microfabrication.

The semiconductor wafer according to the embodiments of the present invention is an intermediate product for manufacturing such a semiconductor device as set out hereinabove and is preferably separated into final pieces of semiconductor device. This allow a multitude of semiconductor devices in good productivity.

Next, preferred embodiments of the present invention are illustrated with reference to the accompanying drawings.

### Embodiment 1

In Embodiment 1, wafer-level CSP and a method for manufacturing same are, respectively, illustrated mainly as instances of a semiconductor device and a method for manufacturing a semiconductor device according to an embodiment of the present invention.

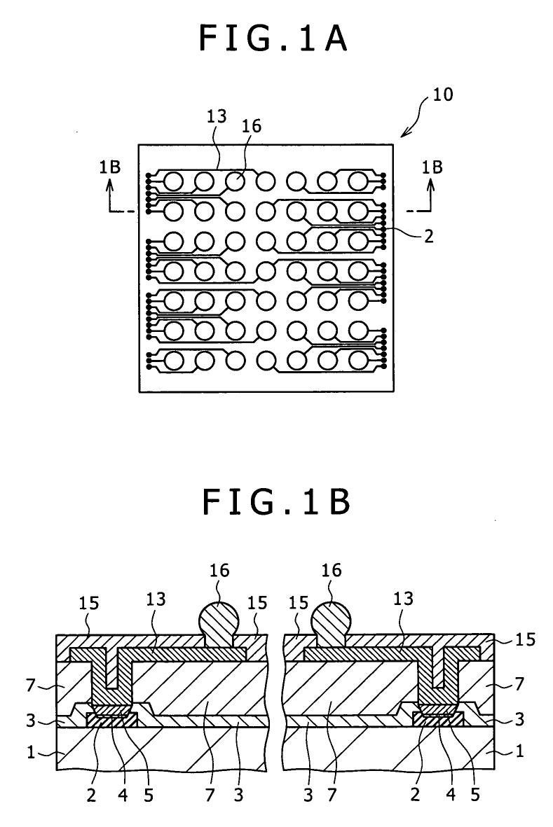

FIGS. 1A and 1B are, respectively, a plan view and a sectional view wherein an active surface side of wafer-level CSP 10 is shown, partly in perspective view. It will be noted that FIG. 1B is a section, taken along line 1B-1B in FIG. 1A, and both end portions are shown while omitting the central portion.

As shown in FIG. 1A, with wafer-level CSP 10, a rewiring layer 13 for extracting a terminal electrode 2 of a semiconductor chip to a position of connection with an external circuit and a solder ball 16 serving as an electrode for external connection with the external circuit at the extracted position are formed in a region with substantially the same size as the semiconductor chip, and are sealed with an insulating resin serving also as a solder resist 15 thereby completing packaging. This enables high-density mounting on a mounting substrate.

It will be noted that with the instance of FIG. 1A, the terminal electrodes 2 are arranged at peripheral portions at left and right sides of the semiconductor chip, and the solder balls 16 are located at central portions as vertically superposed in the active region of the semiconductor chip. The arrangement is not limited to the above one, e.g. the terminal electrodes 2 may be arranged at peripheral potions at the upper and lower sides and left and right sides of the semiconductor chip.

As shown in FIG. 1B, with the wafer-level CSP 10, semiconductor chips 30 are incorporated in a substrate 1 such as a silicon wafer, and the terminal electrode 2 of the semiconductor chip 30 is formed as exposed from a protective film 3 made of the first insulating layer.

The terminal electrode 2 is formed thereon with an underlying layer for plating made of a zinc (Zn) layer 4 and a nickel (Ni) layer 5, and the rewiring layer 13 is formed as connected with the underlying layer for plating. The zinc layer 4 serving as a contact portion ensures reliable adhesion to an aluminium (Al) layer for the terminal electrode 2, and the nickel-plated layer 5 that is the uppermost portion of the underlying layer for plating ensures reliable adhesion to copper (Cu) of the rewiring layer 13. In this manner, the terminal electrode 2 reliably connects with the rewiring layer 13 and is extracted to a position of connection with the external circuit. The rewiring layer 13 at this connection portion is formed with a bump pad, at which the solder ball 16 to be connected to the external circuit is formed as connected thereto.

The rewiring layer 13 is formed via an insulating resin layer 7 serving as a second insulating layer. The insulating resin layer 7 is attached to the substrate 1 in the form of a semi-solidified insulating resin sheet constituting a resin-coated copper foil (RCC) and can be formed of an inexpensive material such as an epoxy resin without use of a relatively expensive manufacturing apparatus such as a spin coater or the like and also of relatively expensive liquid resin materials such as BCB, polyimides or the like used as a material for semiconductor.

The insulating resin layer 7 having a high accuracy in thickness can be formed, under which when the thickness of the resin layer in the insulating resin sheet is varied, the thickness of the insulating resin layer 7 can be readily changed. Because the insulating resin layer 7 can be formed readily in a thickness of 10 μm or over, e.g. 40 μm, which is difficult to attain when using a liquid resin ordinarily employed in a semiconductor manufacturing process. Thus, high-frequency characteristics of the semiconductor chip are not impeded by means of the insulating resin layer 7.

The insulating resin layer of the insulating resin sheet is pressed in a semi-solidified condition, so that volumetric shrinkage is much smaller than in the case where a liquid resin is coated to form an insulating resin layer. Eventually, this leads to a much smaller stress caused between substrates 1 (wafers), with no problem on the warpage of the substrate 1 (wafer).

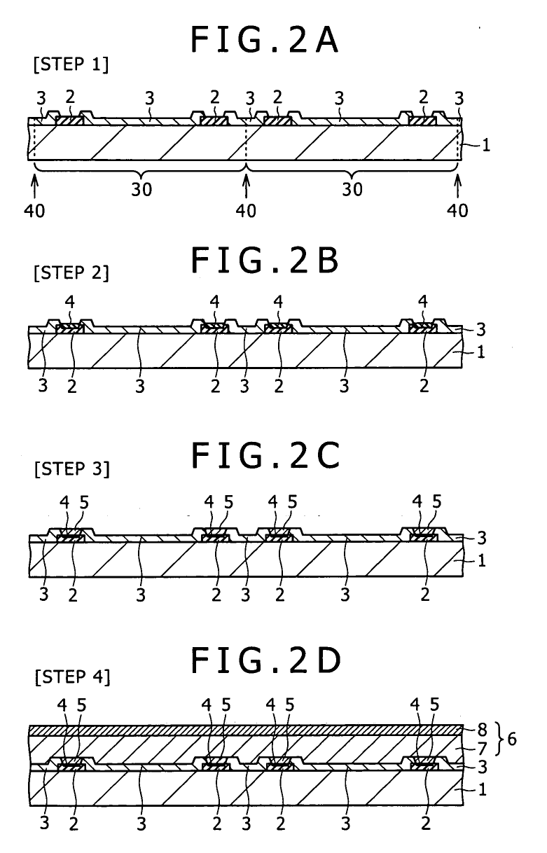

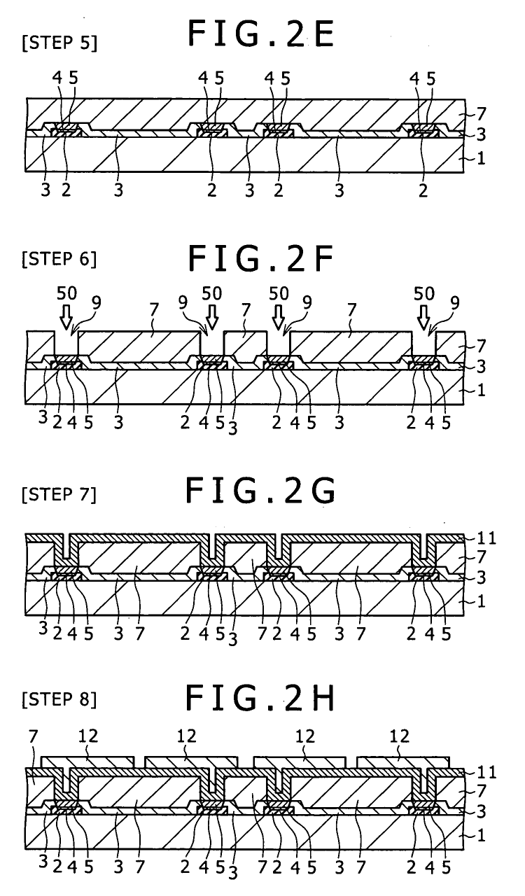

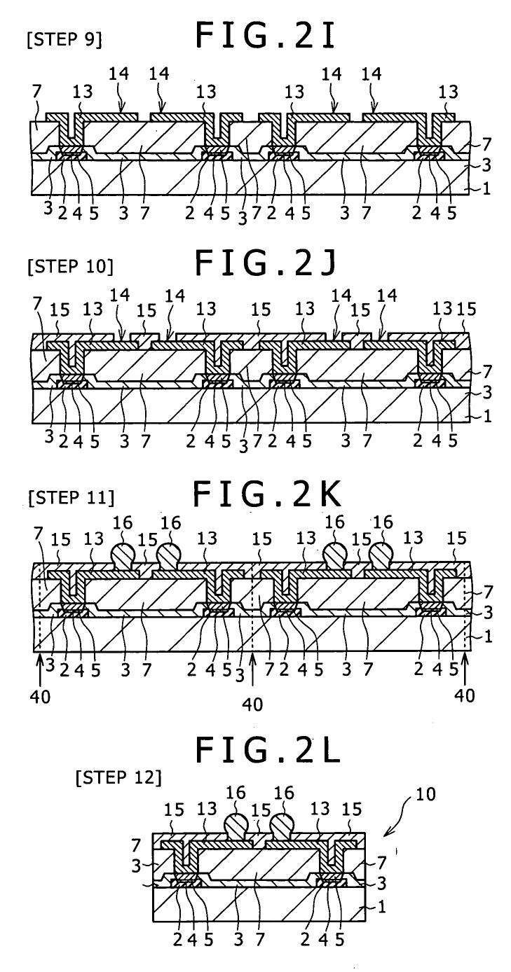

FIGS. 2A to 2L are, respectively, a sectional view showing a manufacturing step of the wafer-level CSP 10. It is to be noted that in most of the following steps, inexpensive materials used in related art manufacturing processes of an organic material substrate and a simple manufacturing apparatus can be effectively applied to, so that the wafer-level CSP 10 can be manufactured at low costs.

[Step 1] Provision of Wafer

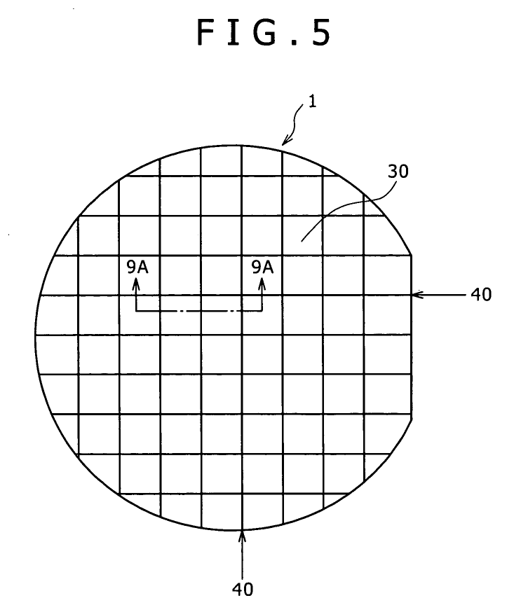

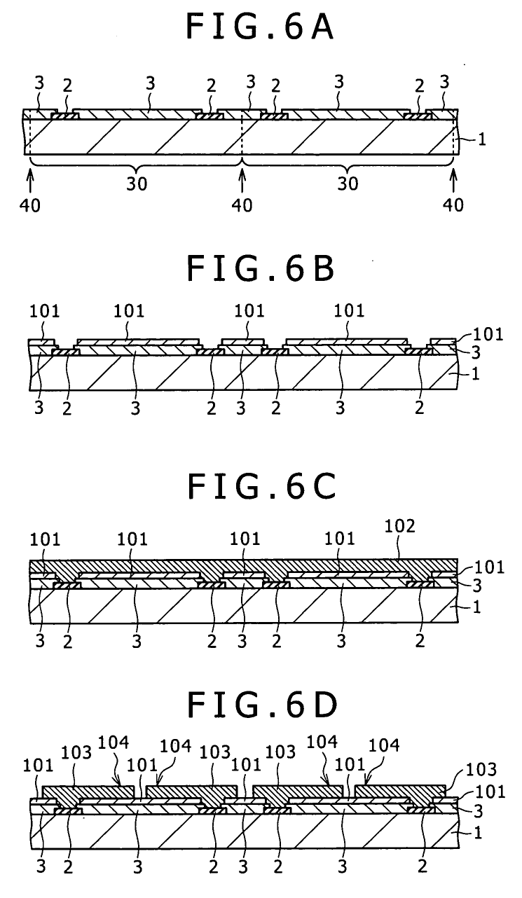

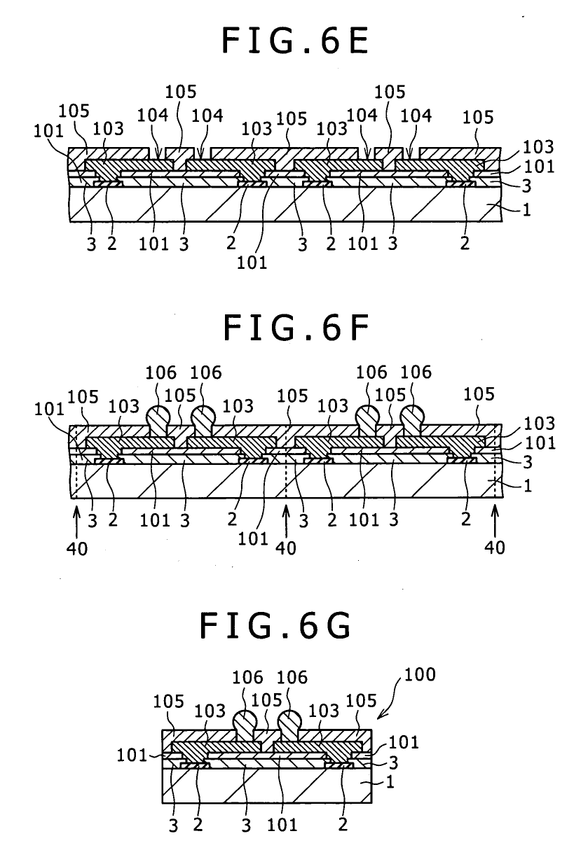

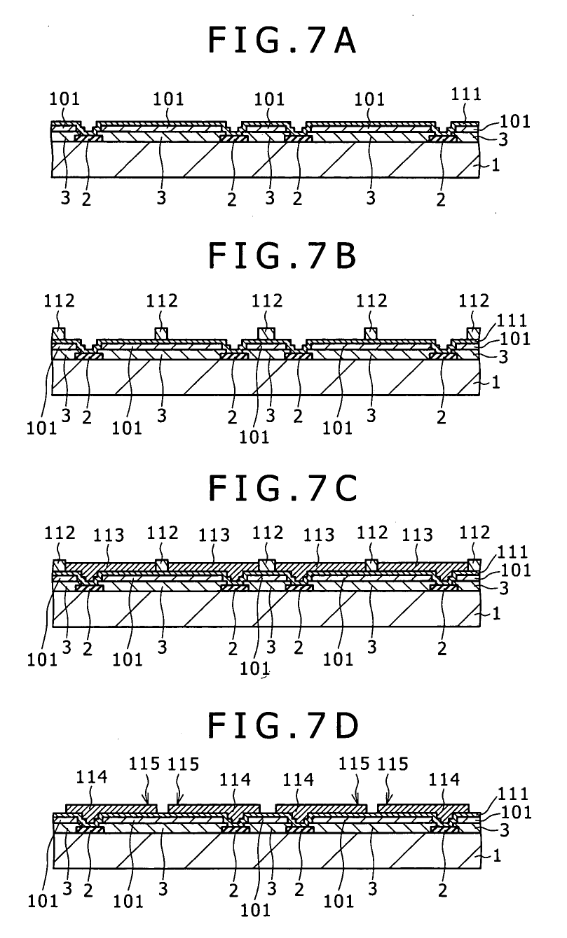

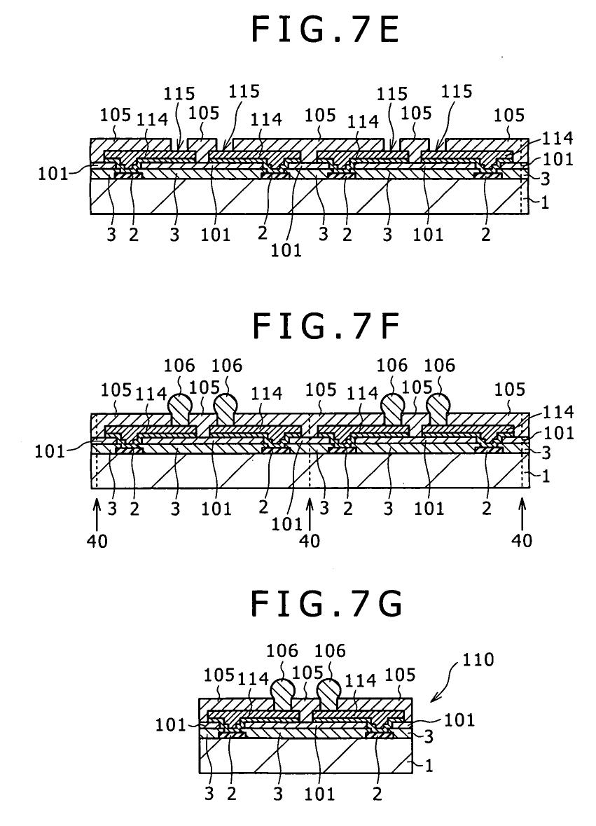

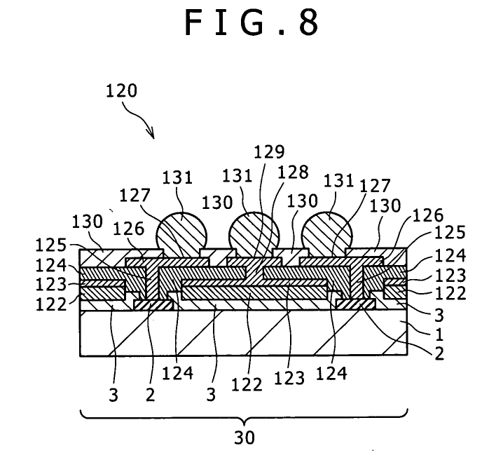

Initially, as shown in FIG. 2A, a wafer to be processed as wafer-level CSP (WL-CSP) based on the present invention, in which LSI (large-scaled integrated circuit) have been incorporated, is provided as substrate 1. This wafer is, for example, a silicon wafer that has an orientation flat or notch as shown in FIG. 5 and has a diameter of 8 inches and a thickness of 725 μm. For instance, a high frequency response device is formed as LSI.

The substrate 1 is formed on the surface thereof with a terminal electrode 2 made of an aluminium layer and a protective layer 3. In steps 2 to 11, a rewiring layer 13 is formed thereon and a solder ball 16 for external connection is mounted.

[Step 2] Zincating of Terminal Electrode 2

As shown in FIG. 2B, a zinc layer 4 having a thickness of about 0.3 μm is formed on the aluminium layer of the terminal electrode 2 by zincating. This zincating is one wherein aluminium or the like is immersed in a solution containing a cation of zinc that is smaller in ionization tendency, and the aluminium in the vicinity of the surface is oxidized and dissolved out to reduce the zinc ion instead, thereby depositing metallic zinc (see Japanese Patent Laid-open No. 2003-13246). This treatment is a sort of electroless plating.

More particularly, the surface of the terminal electrode 2 is treated with diluted sulfuric acid for surface defatting. Next, the terminal electrode 2 is immersed in a zincating solution wherein zinc ions (Zn²⁺) are dissolved to form a zinc layer 4. Thereafter, the surface is treated with diluted sulfuric acid to remove aluminium oxide therefrom, followed by re-immersion in the zincating solution to reliably form a zinc layer 4 of good quality.

With aluminium frequently employed as a material for the terminal electrode 2 of the semiconductor chip 30, a nickel plated layer 5 may not be deposited directly thereon. The oxide on the aluminium surface is removed by zincating to form the zinc layer 4, so that the nickel plated layer 5 can be firmly formed on the zinc layer 4.

[Step 3] Electroless Plating on Terminal Electrode 2

As shown in FIG. 2C, a nickel-plated layer 5 having a thickness of about 5 μm is formed on the terminal electrode 2, on which the zinc layer 4 has been formed, by an electroless plating method. The nickel plated layer 5 is provided as an uppermost portion of the underlying layer for plating and is able to improve plating adhesion upon formation of a copper plated layer 11 bonding to the terminal electrode 2. The nickel-plated layer 5 also serves as a barrier layer, with which copper is prevented from diffusion from the copper-plated layer 11. In addition, the nickel-plated layer 5 also serve as a protective layer when an opening 9 is subsequently formed in the insulating resin layer 7 to expose the terminal electrode 2 thereat, thereby preventing the terminal electrode 2 from change in nature or degradation.

As stated above, the zincating and electroless plating of nickel eventually enable the nickel-plated layer 5 to be reliably, firmly formed on the terminal electrode 2. Since such an underlying layer for plating has been formed beforehand, the rewiring layer can be formed inexpensively by plating, which is one of features of the present invention. Additionally, the zinc layer 4 and the nickel-plated layer 5 are self-alignedly formed, respectively, so that no patterning step is needed and the manufacturing procedure can be simplified.

It will be noted that the method of forming the underlying layer for plating is not limited to the plating method. For instance, according to a sputtering method, a barrier layer and a chromium (Cr) layer serving as an adhesion layer to aluminium may be, respectively, formed, on which a nickel layer serving as an adhesion layer to a plating metal is formed. The underlying layer-forming procedure using the sputtering method can be most readily performed if carried out immediately after the formation of an aluminium layer of the terminal electrode 2 by the sputtering method. In addition, the underlying layer for plating may be formed so as to cover the terminal electrode 2 and a vicinity thereof by use of a metal mask after the formation of the protective layer 3.

[Step 4] Lamination of Resin-Coated Copper Foil (RCC) 6

Next, as shown in FIG. 2D, a resin-coated copper foil (RCC) 6 is laminated on an active surface of a substrate 1. For RCC 6, RCC (product name: MRG 200) made by Mitsui Mining & Smelting Co., Ltd. is used, for example, and is laminated by use of a laminator in the same manner as with the lamination on organic material substrates in related art. Lamination conditions are pursuant to those conditions of lamination on the organic material substrate. According to this step, there are formed, for example, a 40 μm thick insulating resin layer 7 made of an epoxy resin and a 12 μm thick copper foil layer 8.

In the above instance, assuming the case where LSI is a high-frequency device, an example wherein the insulating resin layer 7 is thick is shown. Usually, the insulating resin layer 7 of RCC 6 may be thinner and is conveniently in a thickness, for example, of about 20 μm.

In Embodiment 1, although only the insulating resin layer 7 of RCC 6 is needed as an interlayer insulating layer, a difficulty is involved in that a thin insulating resin layer 7 is handled singly, for which RCC 6 that is easy to handle is used. For this, the copper coil layer 8 is removed in a subsequent step 5. The removal of the copper foil layer 8 is advantageous in that an opening 9 can be formed accurately. If possible, a dry film resist (DFR) may be used in place of RCC 6.

Where, for example, it is desirable that a rewiring layer 13 be thick such as, with the case of a power supply device, a part or whole of the copper foil layer 7 is left for use as a part of the rewiring layer 13. This will later be illustrated in Embodiment 2 appearing hereinafter.

[Step 5] Removal of Copper Foil Layer 8

Next, as shown in FIG. 2E, the copper foil layer 8 is wholly removed by etching. The copper foil layer 8 is removed by oxidation with a hydrochloric acid aqueous solution of ferric chloride (FeCl₃) as in a manner as ordinarily carried out in a manufacturing method of an organic material substrate.

[Step 6] Formation of Opening 9

As shown in FIG. 2F, an opening 9 for extraction of the terminal electrode 2 to outside is formed in the insulating resin layer 7 by irradiation of a UV laser beam 50. The opening 9 has a size, for example, of about 30 μm in diameter and is passed through up to the nickel layer 5 formed at the upper portion of the terminal electrode 2. Thereafter, a smear removing step, not shown, is carried out to remove resin residues left inside the opening 9 for cleaning.

Although the UV laser beam 50 can simply break through the insulating resin layer 7, the beam is unlikely to be absorbed with the nickel layer 5 and is mostly reflected thereat. In this manner, when the opening 9 is formed by irradiation of a laser beam, the nickel layer 5 reflects most of the laser beam and is resistant to high temperatures caused by the irradiation of the laser beam and thus, serves to protect the zinc layer 4 that is a lower layer of the underlying layer for plating and the aluminium layer forming the terminal electrode 2 therefrom. The nickel layer 5 also acts to prevent, in a subsequent smear removing step, a metal such as of the aluminium layer for the terminal electrode 2 from change in nature or degradation by contact with chemicals or solvents.

The UV laser beam 50 is so short in wavelength as to be suited for microfabrication. For a UV laser device, those apparatuses employed in manufacturing methods of organic material substrates in related art are fundamentarily used. Burst processing techniques using a frequency of 25 kHz or the like are used for this purpose, in which in order to enhance a position accuracy, the methods of recognizing a positioning mark image and fixing the substrate (wafer) 1 are improved.

The manner of forming the opening 9 is not critical, but the feature of the invention rather resides in that even if the opening is formed by any of methods, the terminal electrode is protected with the underlying layer for plating. For instance, where the insulating resin layer 7 is made of a photosensitive material, the opening 9 can be simply formed by photolithography.

[Step 7] Formation of Copper Plated Layer 11

Next, as shown in FIG. 2G, a copper (Cu) plated layer 11 is formed wholly over the wafer by a plating method. For the plating, an underlying layer is initially formed by electroless plating in a manner as ordinarily carried out in a manufacturing method of an organic material substrate in related art, followed by electrolytic plating to form an electrolytic copper-plated layer by an electrolytic plating method, e.g. a copper plated layer 11 having a thickness of about 10 μm. The terminal electrode 2 is electrically connected to the surface layer through this copper-plated layer 11.

[Step 8] Lamination and Patterning of Dry Resist Film

As shown in FIG. 2H, a dry film resist (DFR) is laminated as an etching resist on the entire surface of the copper-plated layer 11 to form a photoresist layer having a thickness, for example, of about 15 μm. For DFR, DFR that is ordinarily used, for example, in a manufacturing method of an organic material substrate in related art is used, and a laminator as used for the lamination on an organic material substrate is used for the lamination. Lamination conditions are those pursuant to lamination conditions on organic material substrates in related art. Subsequently, the photoresist layer is exposed to light and developed to form a resist mask 12 having a pattern corresponding to the shapes of a rewiring layer 13 and a bump pad 14.

[Step 9] Patterning of Copper Plated Layer 11

Next, as shown in FIG. 2I, the copper-plated layer 11 is patterned through the resist mask 12 by etching to from a rewiring layer 13 and a bump pad 14. Thereafter, the resist mask 12 is removed by a step not shown.

In this way, there are formed the rewiring layer 13 extracting the terminal electrode 2 of the semiconductor chip to a position of connection with an external circuit and the solder bump pad 14 on which a solder ball 16 is provided for use as an electrode for external connection to be connected with an external circuit at the extracted position.

Thus, when the insulating resin layer 7 is formed using an insulating resin sheet such as RCC, DFR or the like, the insulating resin layer 7 can be formed of an inexpensive material such as an epoxy resin without resorting to relatively expensive manufacturing apparatus such as a spin coater and the like and also to relatively expensive liquid resin materials such as BCB, polyimides and the like.

Further, the insulating resin layer 7 whose accuracy in thickness is high can be formed. When the thickness of the resin layer in the insulating resin sheet is varied, the thickness of the insulating resin layer 7 can be readily changed. In addition, the insulating resin layer 7 can be readily formed in a thickness of 10 μm or over, e.g. 40 μm, which is difficult to attain when using liquid resins ordinarily employed in a semiconductor manufacturing process, so that the high-frequency characteristics of the semiconductor chip are not impeded by means of the insulating resin layer 7.

The insulating resin layer of the insulating resin sheet is pressed in a semi-solidified condition, so that volumetric reduction is far smaller when compared with the case where a liquid resin is coated to form an insulating resin layer. This entails a far smaller stress caused between wafers, with no problem involved based on the warpage of the wafers.

Since the rewiring layer in Embodiment 1 is a single layer, the formation step of the rewiring layer has been completed as stated hereinabove. Where the rewiring layer is formed as multilayered, a series of steps including the steps 4 to 9 are merely repeated. With the case of multilayering, when the insulating resin layer is formed using an insulating resin sheet such as RCC, DFR or the like, the thickness of the insulating resin layer is kept constant and the irregularities caused by the rewiring layer 13 are reliably flattened by the action of the semi-solidified insulating resin layer. When compared with the case of flattening by use of a liquid resin employed in a semiconductor manufacturing process, the multilayered wiring can be formed more readily in higher manufacturing yield.

[Step 10] Formation of Solder Resist 15

Next, as shown in FIG. 2J, a solder resist 15 is formed to cover except for the solder bump pad 14. More particularly, after the formation of a resist material layer over the whole surface including scribing lines, patterning is carried out by exposure to light and development to form the solder resist 15 permitting the solder bump pad 14 alone to be exposed. The size of the opening provided in the solder resist 15 is about 40 μm in diameter. The solder resist material used is, for example, Solder Resist PSR-4000 (commercial name of Taiyo Ink Mfg. Co., Ltd.). The solder resist used for the manufacture of a substrate has its original use as a thick film and thus, a thick insulating film can be readily formed.

[Step 11] Mounting of Solder Ball 16

Next, as shown in FIG. 2K, a solder ball mounting machine used in a BGA (ball grid array) making process is used to print a flux according to a known, ordinarily employed method. A material for solder ball is placed on individual solder pads 14 and the solder ball material is reflowed to form a solder ball 16, followed by cleaning and removing the flux.

[Step 12] Dicing into Individual Pieces

The substrate (wafer) 1, not shown, undergoes the steps of thinning and dicing along scribing lines to obtain individual wafer-level CSP pieces of good quality through final electric measurement.

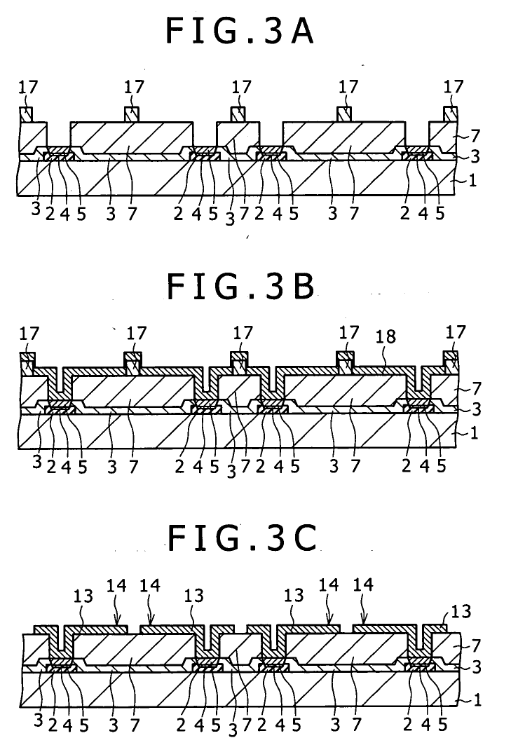

FIGS. 3A to 3C are, respectively, a sectional view showing part of a manufacturing process of wafer-level CSP 10 based on a modification of Embodiment 1. This modification makes use of a lift-off technique to form the rewiring 13 and the solder bump pad 14. The sectional views of FIGS. 3A to 3C are, respectively, ones viewed at the same position as those sectional views of FIGS. 2A to 2L.

According to the foregoing steps 1 to 6, the workpiece shown in FIG. 2F is provided. Next, as shown in FIG. 3A, patterning is carried out by photolithography to form a resist mask 17 having a pattern corresponding to a pattern of the rewiring layer 13 and the bump pad 14.

Thereafter as shown in FIG. 3B, a copper plated layer 18 is formed over the entire surface in the same manner as in FIG. 2G.

As shown in FIG. 3C, the resist mask 17 is removed by dissolution along with the copper-plated layer 18 deposited thereon to leave the copper-plated layer 18 alone serving as a rewiring layer 13 and a solder bump pad 14, thereby forming the rewiring layer 13 and the solder bump pad 14.

Subsequently, waver-level CSP 10 is formed through the steps 10 to 12 illustrated hereinbefore.

As stated above, according to the wafer-level CSP 10 of this embodiment, assuming that the rewiring layer 13 is formed of a plated layer, underlying layers 4, 5 connected to the terminal electrode 2 are provided. Since such pre-processing as mentioned above is carried out, the rewiring layer 13 connected to the terminal electrode 2 can be formed readily, reliably and inexpensively.

Since a plurality of semiconductor chips sequentially disposed on the substrate 1 such as a semiconductor wafer is collectively packaged, this collective package permits high productivity, stability in quality and low manufacturing costs to be realized.

### Embodiment 2

In Embodiment 2, wafer-level CSP 20 and a method for manufacturing same are illustrated as instances of a semiconductor device and a manufacturing method of a semiconductor device according to an embodiment of the present invention.

Embodiment 2 differs in that part of the copper foil layer 8 of RCC 6 is used as a part of the rewiring layer. Others are same as in Embodiment 1 and may not be repeatedly illustrated but emphasis is placed on differences.

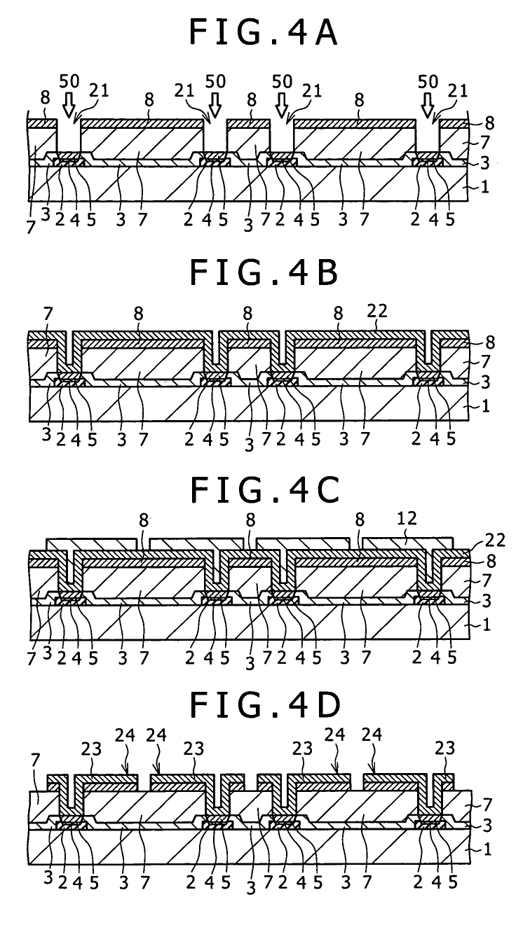

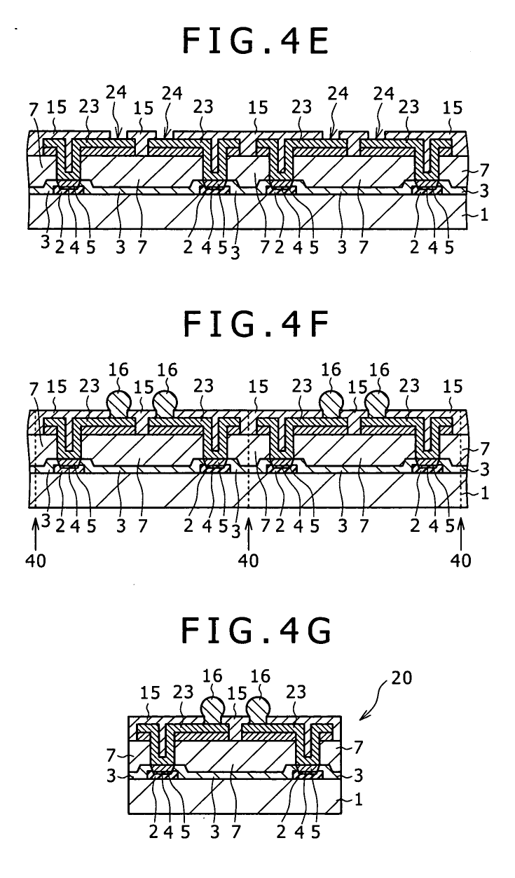

FIGS. 4A to 4G are, respectively, a sectional view showing the step of manufacturing wafer-level CSP 20 based on Embodiment 2. It will be noted that these sectional views are ones viewed at the same position as the sectional views of FIGS. 2A to 2L, respectively.

The steps 1 to 4 are carried out as shown in FIGS. 2A to 2D to provide a workpiece shown in FIG. 2D.

While leaving the copper foil 8, an opening 21 for extracting the terminal electrode 2 to outside is formed in the insulating resin layer 7 and the copper foil layer 8 by irradiation of a UV laser beam 50 as shown in FIG. 4A. The opening 21 is formed to have a size, for example, of about 30 μm in diameter and is passed through to the nickel layer 5 formed on the upper portion of the terminal electrode 2. Thereafter, a resin residue and the like left in the opening 21 are removed and cleaned according to a smear removing step, not shown.

If the copper foil layer 8 is too thick, etching over the entire surface is carried out using a ferric chloride aqueous solution after completion of the step 4 to reduce the thickness of the copper foil layer 8, followed by the above step.

In either case, where the opening 21 is formed by irradiation of a laser beam while leaving the copper foil layer 8, the copper foil surface is oxidized and blackened for conversion to a black color immediately before the irradiation. This allows an absorption efficiency of the laser beam 50 to be improved and thus, the laser power effectively acts on the surface, thereby ensuring a shorter processing time and stable processing.

Next, as shown in FIG. 4B, a copper plated layer 22 is formed in the same manner as in FIG. 2G.

As shown in FIGS. 4C to 4G, the copper foil 8 and the plated layer 22 stacked on the foil 8 are patterned in the same manner as in FIGS. 2H to 2L to form a rewiring layer 23 and a solder bump pad 24. Subsequently, a solder ball 16 is mounted in connection with the solder bump pad 24, followed by separation into individual pieces to complete wafer-level CSP 20.

According to Embodiment 2, the copper foil layer 8 is used as a part of the rewiring layer 23, so that the thickness of the rewiring layer 23 can be increased to reduce the resistance of the rewiring layer 23. This is suited for the formation of a signal line in which a low resistance is important, a signal line through which a great current passes, and a power supply line. Others are the same as in Embodiment 1 and thus, it is needless to say that similar effects and advantages as in Embodiment 1 can be obtained with respect to common features resulting from these embodiments.

As will be apparent from the foregoing, the semiconductor device and method for manufacturing same, and the semiconductor wafer according to the embodiments of the present invention, which make full use of the feature of wafer-level chip space packages capable of realizing low manufacturing costs, are provided, thus contributing to the fabrication of portable, small-sized electronic devices that are small in size, lightweight, thin and low at costs.

The invention has been illustrated based on the embodiments of the invention, which should not be construed as limiting the invention thereto. Many variations and alterations may be possible without departing from the spirit of the invention.

1. A semiconductor device comprising:
a semiconductor chip;
a first insulating layer covering said semiconductor chip in a condition where at least a portion of a terminal electrode of said semiconductor chip is exposed;
a second insulating layer formed over the first insulating layer; and
a rewiring layer extracting the terminal electrode of said semiconductor chip via said second insulating layer to a position of connection with an external circuit;
wherein an underlying layer for plating connected with the terminal electrode is provided in an existing area of the terminal electrode alone or in a region covering from the existing area to above said first insulating layer, and
at least a part of said rewiring layer is formed of a plated layer formed on said underlying layer.

2. The semiconductor device according to claim 1, wherein said underlying layer for plating is constituted of a single layer or a stacked multilayer and a contact portion with said terminal electrode is formed by an electroless plating method.

3. The semiconductor device according to claim 2, wherein the contact portion is made of a zincated layer.

4. The semiconductor device according to claim 1, wherein said underlying layer for plating is constituted of a single layer or a stacked multilayer and an uppermost portion of a layer is made of a high melting metal.

5. The semiconductor device according to claim 4, wherein the layer made of a high melting metal is a nickel layer.

6. The semiconductor device according to claim 1, wherein at least a part of said plated layer is an electroless plated layer formed by an electroless plating method.

7. The semiconductor device according to claim 1, wherein said second insulating layer is made of a laminated insulating resin layer.

8. The semiconductor device according to claim 7, wherein said insulating resin layer used is a copper foil layer-laminated insulating resin layer and part of said copper foil layer is used as a part of said rewiring layer.

9. A semiconductor wafer comprising
a plurality of the semiconductor devices defined in claim 1 sequentially disposed thereon.

10. The semiconductor wafer according to claim 9, wherein said plurality of semiconductor devices are separated into pieces, each containing at least one semiconductor device.

11. A method for manufacturing a semiconductor device comprising the steps of:
providing a semiconductor wafer having a plurality of semiconductor chips sequentially;
forming a first insulating layer to cover individual semiconductor chips in such a state that at least a part of a terminal electrode of each semiconductor chip is exposed;
forming an underlying layer for plating, connected with the terminal electrode, in an existing region of the terminal electrode or in an area covering from the existing region to above said first insulating layer collectively against the plurality of semiconductor chips formed on said semiconductor wafer;
forming a second insulating layer over said first insulating layer;
forming an opening in said second insulating layer to expose the terminal electrode;
forming a rewiring layer, at least a part of which is formed by a plating method, from the opening to above the second insulating film, thereby providing a plurality of semiconductor devices sequentially disposed on the semiconductor wafer; and
separating the plurality of semiconductor devices into pieces, each containing at least one semiconductor device.

12. The method for manufacturing the semiconductor device according to claim 11, wherein said underlying layer for plating is formed as a single layer or a multilayer whose contact portion with said terminal electrode is formed by an electroless plating method.

13. The method for manufacturing the semiconductor device according to claim 12 wherein the contact portion is formed by zincating of a metal layer constituting said terminal electrode.

14. The method for manufacturing the semiconductor device according to claim 11, wherein said underlying layer is formed as a single layer or a stacked multilayer whose upper portion is formed of a layer made of a high melting metal.

15. The method for manufacturing the semiconductor device according to claim 14, wherein at least a part of the layer made of the high melting metal is formed by electroless plating of nickel.

16. The method for manufacturing the semiconductor device according to claim 11, wherein at least a part of the plated layer is formed by electroless plating.

17. The method for manufacturing the semiconductor device according to claim 11, wherein an insulating resin sheet is laminated on a surface of said first insulating layer to form said second insulating layer.

18. The method for manufacturing the semiconductor device according to claim 17, wherein said insulating resin sheet used is a copper foil layer-attached insulating resin sheet, and at least a part of the copper foil layer is used as a part of said rewiring layer.

19. The method for manufacturing the semiconductor device according to claim 11, wherein said opening is formed by irradiation of a laser beam.
